(19) United States
(12) Patent Application Publication
(10) Pub. No.: US 2009/0146253 A1
(43) Pub. Date: Jun. 11, 2009

(54) SEMICONDUCTOR DEVICE AND METHOD OF MANUFACTURING THE SAME

(76) Inventor: Ki-Jun Yun, Suwon-si (KR)

Correspondence Address: SHERR & VAUGHN, PLLC, 620 HERNDON PARKWAY, SUITE 200, HERNDON, VA, 20170, US

(21) Appl. No.: 12/330,654

(22) Filed: Dec. 9, 2008

(30) Foreign Application Priority Data
Dec. 10, 2007 (KR) 10-2007-0127517

(51) Int. Cl. H01L 21/02; H01L 29/86

(52) U.S. Cl. 257/531; 438/381; 257/E21.022; 257/E29.325

(57) ABSTRACT

Manufacturing an inductor includes forming a spiral metal wire on a semiconductor substrate; forming a connection hole exposing a portion of the metal wire by selectively etching a first dielectric film formed to bury the metal wire, and forming a first metal film on the first dielectric film on which the connection hole is formed; forming a second dielectric film on the first metal film; and forming a first photoresist film for forming a second metal wire corresponding to the spiral metal wire on the second dielectric film, and forming the second metal wire by selectively etching the second dielectric film and the first metal film using the first photoresist pattern as an etching mask; wherein the second dielectric film prevents an etching of the top of the second metal wire resulting from the difference in etch rate between the first photoresist pattern and first metal film.

The present application claims priority under 35 U.S.C. 119 to Korean Patent Application No. 10-2007-0127517 (filed on Dec. 10, 2007), which is hereby incorporated by reference in its entirety.

### BACKGROUND

An inductor, which is a passive device capable of transmitting and receiving high frequency signals, has been used in radio frequency (RF) devices and analog devices and increasingly so, as the wireless communication market has grown. The inductor occupies the largest area in a chip as a single device, compared to a transistor, a capacitor and a resistor, and has many restrictions in high frequency characteristics including the peripheral materials, structures, parasitic capacitance and resistance components resulting from the internal material.

The inductor is implemented by bending a upper-most metal of a substrate on a two-dimensional plane, wherein the inductor may be formed in a rectangular type, an octagonal type, a circular type and the like, and may further be formed in a spiral type. FIG. 1 is a plane view of a related spiral inductor. The spiral inductor includes a first metal wire 3 having a spiral winding structure, and a second metal wire 5 formed on a bottom connected to the first metal wire 3 through a via contact.

In order to improve the quality factor Q of an inductor used in a RF chip, that is, in order to implement a high Q inductor having high inductance, a thickness of the first metal wire 3 should be increased or a thickness of an oxide layer formed on the bottom of the first metal wire 3 should be reduced. FIG. 2A is a general cross-sectional view prior to an etching process for implementing a related high-Q inductor, and FIG. 2B is a cross-sectional view after an etching process for implementing a related high-Q inductor. As shown in FIG. 2A, the high Q inductor prior to the etching process includes a first dielectric film 15 and second dielectric films 20 and 40 formed on a semiconductor substrate 10. It also includes a first spiral metal wire 30 formed on the first dielectric film 15, a second metal film 50 formed on the first metal wire 30 and second dielectric film 40, and a photoresist pattern 55 formed corresponding to the first metal wire 30 formed on the second metal film 50.

As shown in FIG. 2B, during the etching process for implementing the related high Q inductor, the second metal film 50 has a small etching quality factor for the photoresist pattern 55 so that a problem may arise in that a top 53 of a second metal wire 52 may be etched after the etching process thereby preventing implementation of the high Q inductor.

### SUMMARY

Accordingly, embodiments relate to a high-Q inductor wherein a top of a metal wire which forms the inductor is prevented from being etched during an etching process for implementing the inductor, and a method of manufacturing the same.

Embodiments relate to a method of manufacturing an inductor of a semiconductor device that includes: forming a spiral, first metal wire on and/or over a semiconductor substrate; forming a connection hole exposing a portion of the first metal wire by selectively etching a first dielectric film formed to bury the first metal wire, and forming a first metal film on and/or over the first dielectric film on which the connection hole is formed; forming a second dielectric film on and/or over the first metal film; and forming a first photoresist film for forming a second metal wire corresponding to the first metal wire on and/or over the second dielectric film, and forming the second metal wire by selectively etching the second dielectric film and the first metal film using the first photoresist pattern as an etching mask. In accordance with embodiments, the second dielectric film prevents an etching of the top of the second metal wire resulting from the difference in etch rate between the first photoresist pattern and first metal film.

Embodiments relate to an inductor of a semiconductor device includes a spiral, first metal wire formed on and/or over a semiconductor device; a first dielectric film formed to bury the first metal wire and having a connection hole exposing a portion of the first metal wire; a second metal wire formed corresponding to the first metal wire by selectively etching a metal film formed on and/or over the first dielectric film and being connected electrically to the first metal wire through the connection hole; and a second dielectric film formed on and/or over the second metal wire in order to prevent the top of the second metal wire from being etched during the etching process for forming the second metal wire.

### DRAWINGS

FIG. 1 is a plane view of a spiral inductor.

FIG. 2A is a cross-sectional view prior to an etching process for implementing a high-Q inductor.

FIG. 2B is a cross-sectional view after an etching process for implementing a high-Q inductor.

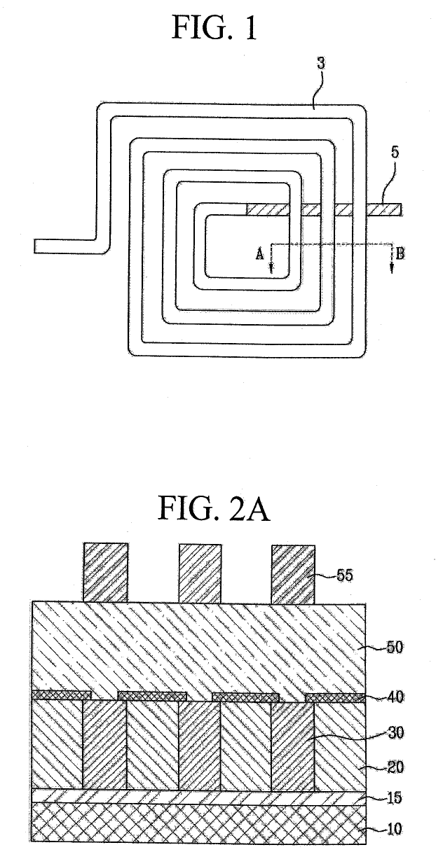

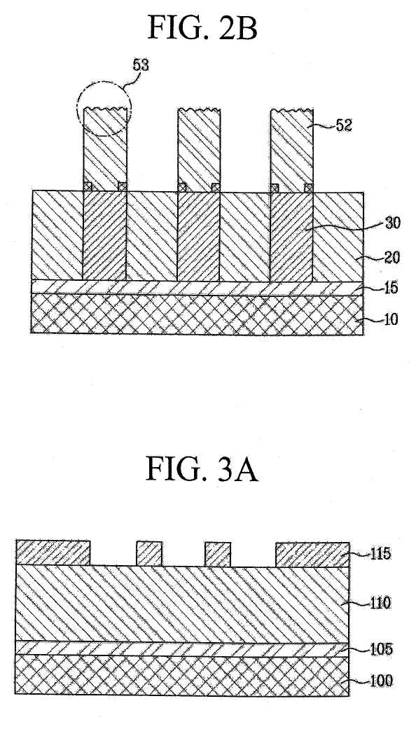

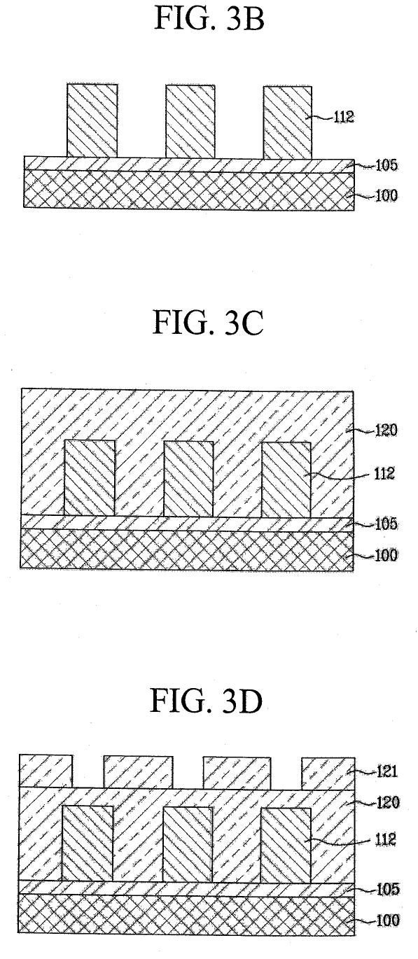

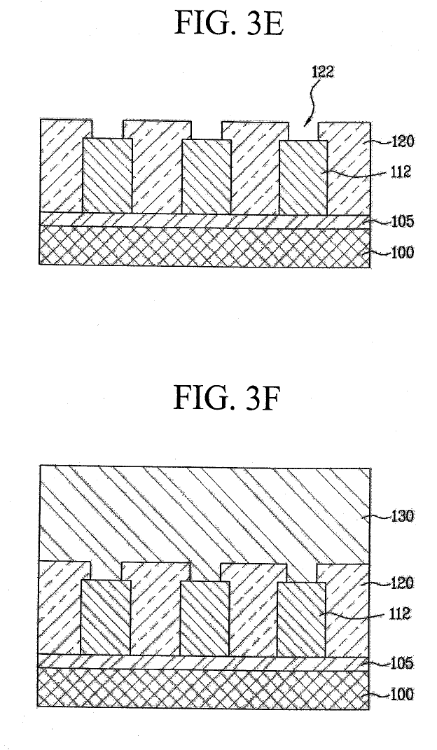

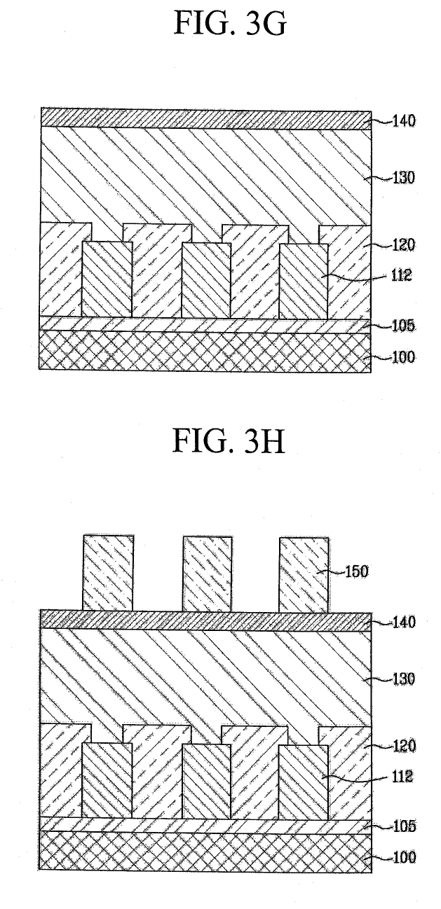

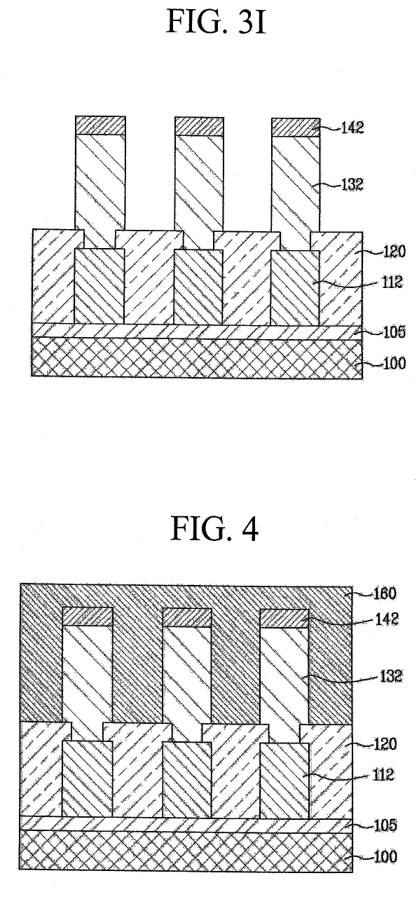

Example FIGS. 3A to 3I show a method of manufacturing an inductor of a semiconductor device according to embodiments.

Example FIG. 4 is a cross-sectional view of an inductor of a semiconductor device according to embodiments.

### DESCRIPTION

Example FIGS. 3A to 3I are cross-sectional views showing steps of a method of manufacturing an inductor of a semiconductor device according to embodiments. First, as shown in example FIG. 3A, a first dielectric film 105 may be formed on and/or over a semiconductor substrate 100, and a first metal film 110 may be formed over substantially all of the first dielectric film 105. The first dielectric film 105 may be made, for example, of tetraethoxysilane (Si(OC2H5)4), and the first metal film 110 may be made of, for example, copper (Cu). A spiral or otherwise helix-shaped first photoresist pattern 115 may be formed on and/or over the first metal film 110 through exposure and development processes.

Next, as shown in example FIG. 3B, the first metal film 110 may be selectively etched using the first photoresist pattern 115 as an etching mask to form a first metal wire 112. Next, as shown in example FIG. 3C, a second dielectric film 120 may be formed on and/or over the first metal wire 112 so that the first metal wire 112 is buried. As shown in example FIG. 3D, a second photoresist pattern 121 may be formed on and/or over the second dielectric film 120 in order to expose a portion of the top of the first metal wire 112.

Next, as shown in example FIG. 3E, the second dielectric film 120 is selectively etched using the second photoresist pattern 121 as an etching mask to form a connection hole 122 exposing the portion of the top of the first metal wire 112. As shown in example FIG. 3F, a second metal film 130 may be formed on and/or over, the second dielectric film 120 on and/or over which the connection hole 122 is formed. The second metal film 130 may be formed to be thicker than the connection hole 122 in order to aid in implementing a high-Q inductor.

Next, as shown in example FIG. 3G, a third dielectric film 140 may be formed on and/or over the second metal film 130. As shown in example FIGS. 3H and 3I, a third photoresist pattern 150 to form a second metal wire 132 corresponding to the first metal wire 112 may be formed on and/or over the third dielectric film 140 so that the third dielectric film 140 and second metal film 130 may be etched, using the third photoresist pattern 150 as an etching mask, to form the second metal wire 132.

In accordance with embodiments, the third photoresist pattern 150 may be formed so that a border line of the second metal wire 132 is aligned with that of the first metal wire 112. One benefit of the third dielectric film 140 is that it may prevent the etching of the top of the second metal wire 132 generated due to the differences in etching rate between the third photoresist pattern 150 and the second metal film 130. For example, the second dielectric film 120 may have a rapid etch rate and a large etching selectivity with the third photoresist pattern 150, thereby sufficient etching margins can be secured by forming the photoresist pattern 150 to an appropriate thickness. For example, the thickness of the third photoresist pattern 150 may be about 2.4 μm. However, the second metal film 130 may have a small selectivity with the third photoresist pattern 150, thereby etching margins may be insufficient.

Here, the etching selectivity (SR=Ef/Er) represents a ratio of an etch rate of a bottom of a film (Ef, for example, an etch rate of the second metal film 130) to an etch rate of a mask layer (Er, for example, an etch rate of the third photoresist pattern 150). The top of the second metal wire 132 formed by selectively etching the second metal film 130 using the third photoresist pattern 150 as an etching mask may, itself, be etched as the third photoresist pattern 150 is consumed. The undesirable result is that the thickness of the second metal wire 132 may be reduced, thus, making it difficult to implement a high-Q inductor.

Therefore, the third dielectric film 140 is additionally deposited on the second metal film 130 to prevent the thickness of the second metal wire 132 from being reduced due to the etching of the top of the second metal wire 132, making it possible to form a high-Q inductor. The thickness of the third dielectric film 140 may vary but may, for example, be between about 4000 Å to 6000 Å. The thickness of the second metal wire 132 may also vary and may, for example, be between about 22000 Å to 42000 Å, such as, around 30000 Å. The third dielectric film 140 may be a material having a small etching selectivity with the second metal film 130. For example, the third dielectric film 140 may be silicon oxide film (SiO2) or tetraethoxysilane (Si(OC2H5)4).

Also, according to embodiments, a subsequent process for forming the high-Q inductor may be performed without a separate step of removing the third dielectric film 140, making it possible to simplify the process. Example FIG. 4 is a cross-sectional view of an inductor of a semiconductor device according to embodiments. Referring to example FIG. 4, the inductor of the semiconductor device includes a first dielectric film 105 formed on, or over, a semiconductor substrate 100, a spiral, first metal wire 112 formed on, or over, the first dielectric film 105, a second dielectric film 120 formed to bury the first metal wire 112 and having a connection hole exposing a portion of the first metal wire 112, a second metal wire 132 formed corresponding to the first metal wire 112 by selectively etching a metal film formed on, or over, the second dielectric film 120 and connected electrically to the first metal wire 112 through the connection hole, and a third dielectric film 142 formed on, or over, a top of the second metal wire 132. Also, the inductor of the semiconductor device may further include a fourth dielectric film 160 formed so as to bury the second metal wire 132 having the third dielectric film 142 on the top of the second metal wire 132.

As described in example FIG. 3H, the third dielectric film 142 formed on the top of the second metal wire 132 may prevent the etching of the top of the second metal wire 132 during the etching process for forming the second metal wire 132. The dielectric film may be additionally deposited on the metal film for forming the metal wire of the inductor to prevent reduction in thickness of the second metal wire in accordance with the etching of the top of the second metal wire during the etching process, beneficially forming the high-Q inductor. Also, subsequent processing may be performed without an additional, separate step of removing the dielectric film deposited on the metal film after the etching process for forming the metal wire of the inductor, making it possible to simplify the process.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a spiral, first metal wire over a semiconductor substrate; and then
forming a connection hole exposing a portion of the first metal wire by selectively etching a first dielectric film formed to substantially bury the first metal wire; and then
forming a first metal film over the first dielectric film in which the connection hole is formed; and then
forming a second dielectric film over the first metal film; and then
forming a first photoresist pattern over the second dielectric film; and then
forming a second metal wire by selectively etching the second dielectric film and the first metal film using the first photoresist pattern as an etching mask.

2. The method of claim 1, wherein etching of the top of the second metal wire results from a difference in etch rate between the first photoresist pattern and first metal film.

3. The method of claim 1, wherein the second metal wire corresponds to the first metal wire.

4. The method of claim 1, wherein forming the connection hole comprises:
forming the first dielectric film on the spiral, first metal wire, filling spaces between the first metal wires; and then
forming a second photoresist pattern over the first dielectric film; and then
selectively etching the first dielectric film using the second photoresist pattern as an etching mask to form the connection hole.

5. The method of claim 1, wherein the first photoresist pattern is formed to align an edge the second metal wire with that of the first metal wire.

6. The method of claim 1, wherein the second dielectric film is formed at a thickness in a range between approximately 4000 Å to 6000 Å.

7. The method of claim 1, wherein the second metal wire is formed at a thickness in a range between approximately 22000 Å to 42000 Å.

8. The method of claim 1, wherein the second dielectric film remaining on the top of the second metal wire after the second metal wire is formed is not removed.

9. The method of claim 8, further comprising:
forming a third dielectric film over the top of the second metal wire and the remaining second dielectric film.

10. The method of claim 1, wherein the second dielectric film comprises a silicon oxide film.

11. The method of claim 1, wherein the second dielectric film comprises tetraethoxysilane.

12. An inductor of a semiconductor device comprising:
a spiral first metal wire formed over a semiconductor device;
a first dielectric film, substantially covering the spiral first metal wire and having a connection hole exposing a portion of the spiral first metal wire;
a second metal wire formed corresponding to the spiral first metal wire; and
a second dielectric film formed over the second metal wire in order to reduce etching of a top of the second metal wire during an etching process for forming the second metal wire.

13. The inductor of claim 12, wherein the second metal wire is formed by selectively etching a metal film formed on the first dielectric film.

14. The inductor of claim 12, wherein the spiral first metal wire is electrically coupled with the second metal wire through the connection hole.

15. The inductor of claim 12, further comprising:
a third dielectric film formed over the second metal wire and the second dielectric film on the top of the second metal wire.

16. The inductor of claim 12, wherein the thickness of the second dielectric film is in a range between approximately 4000 Å to 6000 Å.

17. The inductor of claim 12, wherein the thickness of the second metal wire is in a range between approximately 22000 Å to 42000 Å.

18. The inductor of claim 12, wherein the second dielectric film comprises silicon dioxide.

19. The inductor of claim 12, wherein the second dielectric film comprises tetraethoxysilane.

20. The inductor of claim 12, wherein the second dielectric film has a small etching selectivity with respect to the second metal wire.
